(19) United States
(12) Patent Application Publication
(10) Pub. No.: US 2020/0367394 A1
(43) Pub. Date: Nov. 19, 2020

(54) Sheet for use in operations involving a scanner

(71) Applicant: Lisa Gineris, Cedar Lake, IN (US)

(72) Inventor: Lisa Gineris, Cedar Lake, IN (US)

(21) Appl. No.: 15/931,641

(22) Filed: May 14, 2020

Related U.S. Application Data
(60) Provisional application No. 62/848,717, filed on May 16, 2019.

(51) Int. Cl. H05K 9/00

(52) U.S. Cl. CPC H05K 9/0043; G06K 7/1417; H05K 9/0094; H05K 9/0058

(57) ABSTRACT

A bag, or sheet, useful for preventing electronic barcode scanners from identifying unwanted labels that appear in the field of view of such a scanner, or other similar electronic reader. The invention provides a means for blocking the scanning of undesired item identifiers, such as barcodes, for products being packed then shipped while allowing specific desirable product identifiers to be read by the scanner.

### CROSS-REFERENCE TO RELATED APPLICATIONS

The present application claims the benefit of U.S. Provisional Patent Application No. 62/848,717, filed May 16, 2019, the entirety of which is hereby incorporated by reference.

### BACKGROUND

Industry regularly uses electronic devices to read symbols, such as bar codes or alphabetic characters, that appear on printed labeling. Computerized scanners are used to read these symbols. The most recognizable of these symbols are the black-and-white zebra lines found on products used by people every day.

Scanners are extremely adept at determining when such a symbol is within its field of view. Once determined, the scanner interprets the meaning of the symbol and digitally passes that information to a computerized system. The system interprets the information received and acts on it, determining the exact product contained in a box to which the label is attached for example.

Commonly seen are scanners with light emitting diodes that shine a first light onto a barcode label, to name one example of a symbol. The first light is altered by the symbols and a second light then reflects back from the barcode. The second light is received by a light-detecting photoelectric cell. The differences between the first and the second lights is interpreted by a computer to signify a particular piece of information.

The scanner technology has advanced. The ease and speed at which a scanner can identify a label, interpret its symbols, and transfer information about that symbol to a computer has surpassed human abilities to do the same. This ease and speed of detection makes it particularly problematic for situations where many labels exist for many products in small spaces, such as in a product fulfillment center to name one example.

Currently, fulfillment centers, or the like, are tasked with managing large amounts of inventory for products of many different types. The center receives orders that must be filled quickly and efficiently. The fulfillment center holds product from many different vendors and receives orders from many different customers. A problem arises when there is a requirement to bundle products into a single sellable item. For instance, a customer may order a cup made by one vendor along with coffee product made by another vendor. The users in a fulfilment will be tasked with preparing a package that contains the items ordered, picking each item ordered of the shelves in the center's inventory. The final package shipped to the customer will have its own barcode. That barcode will be different from the product vendor barcodes. The fulfillment center will use its own labels and symbols. This creates a problem where there a multitude of labels present within an electronic scanner's range of scanning.

Presently, to solve this problem of multiple different labels appearing alongside one another, workers will manually control the direction of scanners to scan only the label that a user feels is needed. Too, workers are tasked with physically marking out labels and symbols that are not to be read by in scanning operations. For instance, if several products are located in one product bin, each having their own barcode, these barcodes will be marked out with a dark colored marker, placed in a clear bag, and the appropriate label then placed on the bag. These processes to resolve the problem are labor intensive and ineffective due to the bag is clear or even semitransparent.

There is a need in the industry for an apparatus that can be use used to prevent scanners from identifying unwanted labels that appear in the field of view of scanners, or other similar electronic readers. It should do this without adding labor to an already labor-intensive fulfillment center's processing.

### SUMMARY

The present invention is directed to an article that satisfies this need. An embodiment of the article comprises a sheet for use in operations involving a barcode scanner, that is a device used in industry for reading barcodes and other types of product codes often referred to as UPCs. The sheet comprises a first portion, a first layer for instance. Then there is a blocking portion, another layer for instance. There is a second identifier, usually in the form of a barcode.

The first portion is transparent, at least to the point that items placed on one side of the sheet can be seen through the first portion. Presently, warehouse requirements are that this portion be totally transparent but there is no reason why the invention would not work with semi-transparent portions. It is desired that objects can be seen through the sheet. A blocking portion is attached to the first portion with the second identifier being attached to the blocking portion. It is envisioned that the second identifier would be smaller in area than the blocking portion and that the second identifier could be a sticker, to name one example.

The sheet being interposable between the scanner and at least one first identifier, a barcode for instance, such that the blocking portion obscures the at least one first identifier from scanning by the scanner. The at least one first identifier is attached to product pieces that are to be shipped by the center. By placing the sheet in between a barcode scanner and a product piece that has affixed to it an at least one first identifier, the barcode scanner is prevented from reading (due to the blocking portion being affixed to the first portion) the at least one identifier. The result being that the scanner reads only the second identifier despite there being products having varied or the same at least one first identifiers positioned within range of the scanner's optics.

Because the sheet can be used in a warehouse environment (or the like), it is desirable to have sheets located throughout the warehouse for easy reach and use. Therefore, it is envisioned that the sheet would include the first portion having at least two holes. In that way, the sheets can be removably attached, e.g. attachable and detachable, to a wicket via the at least two holes. Wickets are commonly used in industry. The invention can also have an adhering portion, a strip of adhesive on one or all edges of the sheet for instance, for attachment to a container or for attachment to itself when forming a bag. The adhering portion can be by adhesive or magnetic strip to name just two examples. This way a sheet can be slapped over the UPC codes (first identifiers) that are placed on boxes by others, for instance. The blocking portion would prevent those UPC codes from being read by a scanner which would only read the second identifier placed on the sheet.

Notably, the sheet's blocking portion is a plurality of markings, these can be any symbols or marks. However, it has been found best when the plurality of markings are printed lines. These printed lines are attached to the first portion by a manufacturing process that is not new, heat or ink to name two examples. Too, the markings need only provide sufficient cover to cause the blocking of scanner rays though the blocking portion could be the same size and shape as the first portion.

The markings can be any means for performing the obscuring, blocking, function that is essential to the invention, the best mode being printed rays, or lines, however it is envisioned that there are other means to obscure. For instance, a translucent material, a liquid, a particulate, or any other means for interfering with scanning machine technologies for identifying presented symbols. The lines being capable of preventing machine reading of printed symbols when such printed symbols are placed behind the printed lines.

The at least one first identifier can be a first barcode and the second identifier can be a second barcode. However, as industry progresses there may prove to be other identifiers that become commonly used to identify products. The invention would work to block first identifiers to the extent that a scanner is used to read them.

The best mode of the sheet is where the first portion is formed into a bag and is made from flexible plastic. Such a bag allows a warehouse person to place within the bag different products, each having different at least one first identifiers. The products are viewable through the first portion. The blocking portion does not block seeing the contents inside the bag, instead the blocking portion blocks scanners from reading the first identifiers.

So, a sheet for use in operations involving a scanner, such as a UPC scanner, has a first portion, a blocking portion, and a second identifier. The first portion being transparent and being flexible plastic. The first portion having at least two holes.

The sheet also has the blocking attached to the first portion. This is done today by layering the blocking portion onto all or a large area of the first portion. Certainly, the blocking portion does no lay over all of the first portion. There is the second identifier which is attached to an area of the blocking portion, covering it by adhesion for instance.

The sheet is interposable between the scanner and at least one first identifier such that the blocking portion obscures the at least one first identifier from scanning by the scanner. So, when a user points the scanner at the bag, the scanner may have several barcodes in its scanning range but only the second identifier will be recognizable to the scanner. And the first portion being attachable and detachable to a wicket via the at least two holes allows for easy placement and use of the sheets.

Now, the blocking portion can be a plurality of markings, these can be anything that interferes with the scanning function of a scanner. Though today the markings are printings, it is envisioned that any marking that interferes with a scanner for reading product codes would make up the blocking portion. For one embodiment, the plurality of markings being printed lines and the first portion might have an adhering portion for attachment to a container or to itself. The at least one first identifier is a first barcode and the second identifier is a second barcode.

An embodiment of the sheet for use in operations involving a scanner has a first portion, a blocking portion, and a second identifier, a barcode to name one example of an identifier. The first portion being transparent and having at least two holes.

The blocking portion being attached to the first portion, such as by heat or printing in the manufacturing process. The second identifier being attached to the blocking portion, by a user placing a sticker, for instance. The sheet being interposable between the scanner and at least one first identifier functions so that, when it is so interposed, the blocking portion obscures the at least one first identifier from scanning by the scanner.

The first portion being attachable and detachable to a wicket via the at least two holes allows for easy placement of the item throughout a warehouse, for instance, where wickets are commonplace. The blocking portion being a plurality of markings, the plurality of markings being printed lines. The first portion being flexible plastic and formed into a bag.

Again, it is important that the at least one first identifier is a first barcode and the second identifier is a second barcode in this embodiment of the present invention. Certainly, in other embodiments, the identifiers may be of other technology such as radio-frequency tags or QR codes to name a few examples.

An embodiment of the sheet involves a sheet used in operations involving a scanner that comprises a first portion, a blocking portion with the first portion being transparent. The blocking portion being a plurality of printed lines.

In the embodiment the first portion having at least two holes and being formed into a bag. The blocking portion being attached to the first portion. Experience in using the invention shows that this is best done by printing the blocking portion, or layer, onto a side of the first portion, or layer.

There is at least one object and at least one first barcode. The at least one object being located within the bag. The at least one first barcode being attached to the at least one object. The inventor has found that workers, warehouse workers for instance, will place several products, often different types, within a bag where each of the types of products has a different first barcode, identifier.

Then there is a second barcode. The second barcode being attached to the blocking portion. And the blocking portion being interposable between the scanner and the at least one first barcode. The at least one first barcode being viewable by a user through the first portion.

The blocking portion, and necessarily the first portion, being so interposed, the blocking portion obscures the at least one first barcode from being scanned by the scanner causing the result that the scanner reads only the second barcode when the optical scanner is directed at the bag.

Again, for ease of placement and use the first portion is attachable and detachable to a wicket via the at least two holes.

The invention offers certain other beneficial aspects. For instance, the amount of time a warehouse worker, for instance, takes to retrieve a product from inventory is decreased because the worker need not worry about barcodes that are not intended to be utilized or scanners reading the wrong identifiers. Too, an embodiment works with a common wicket whereby two holes punched on the top of the sheet formed into a bag, for instance, allows a metal bracket to be put through the holes so the bundle of bags could be secured in a machine used to blow open the bags. The wicket allows the bags to be positioned so it removes the step of opening the bag and the wicket is located so as not to subtract from the function of a blocking or obstructing mechanism attached to the bag. It is understood that an embodiment might include a wicket, however a wicket need not be part of my invention.

The article includes an obstructing mechanism, the blocking portion, such as embedded surface scores, like lines, positioned, for instance running perpendicular to each other, to make it so that the barcodes of items that are located within the bag or on the other side of the sheet cannot be read by an electronic reader, such as a UPC scanner.

Too, an embodiment of the article allows for product to be put inside of bags without marking out the barcodes that come preprinted on products. In some warehouses, all barcodes must be marked out so that there is only one scannable barcode, which is usually a label with a unique product identifier. This takes up a large amount of resources. So, because it provides that barcodes do not need to be marked out or covered by a user, the invention increases the speed of production when placing items in the inventive article when formed into bags. Notably, an embodiment of the apparatus would be easily attachable and detachable to and from any product of inventory and need not be used in only a bag form. Though, the bag form is found today to be the best mode.

For instance. an embodiment of the article can be attached to a larger inventory item, over that item's barcode for example, such that the invention blocks the barcode from being read by a scanner or other electronic reader. So, it can be seen that embodiments of the apparatus can be bag-like or sheet-like. In either, the first portion is sufficiently transparent to allow a person to view the items, or objects, within the bag or behind a sheet of the embodiment.

### DESCRIPTION OF THE SEVERAL VIEWS OF THE DRAWINGS

These and other features, aspects and advantages of the present invention will become better understood with regard to the following description, appended claims, and accompanying drawings where:

FIG. 1 shows a perspective view of an embodiment of the present invention.

FIG. 2 shows another perspective view of an embodiment of the present invention being used in a bar code scanning operation.

FIG. 3 shows a block diagram of an embodiment of the present invention being used in a scanning operation.

### DESCRIPTION

### Overview.

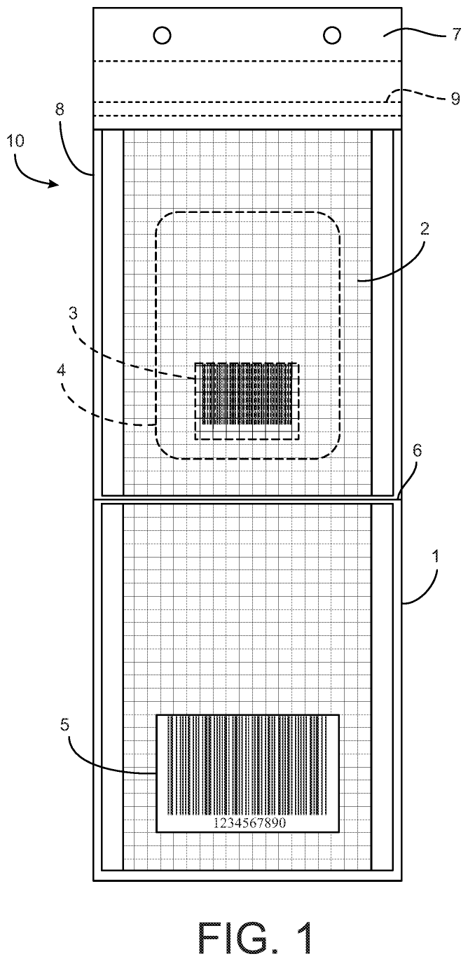

As shown in FIG. 1, an embodiment of the present invention comprises a sheet 10. The sheet 10 is shown in FIG. 1 laid out and unfolded along line 6. A first portion 1, a layer, of the sheet 10 has attached to it a blocking portion 2. In this embodiment the blocking portion 2 is affixed to the surface of the first portion 9 or embedded within the first portion's layer. The blocking portion 2 essentially making up its own layer of the sheet 10. The blocking portion 2 is a plurality of markings, a series of lines. The blocking portion 2 performs an obscuring function so as to obscure the electronic scanning of any product identifier, such as a UPC code, that is placed on either side of the series of lines, that is the blocking portion 2.

In the FIG. 1 embodiment, shown located to one side of the sheet 10, behind it so to speak, is an inventoried item 4, or object, such as product intended for future sale. Warehouses or fulfillment centers, for instance, inventory and ship varied products in different amounts and sizes as orders are received from consumers. The item 4 has affixed to its surface a first identifier 3. The first identifier 3 shown in FIG. 1 is a barcode commonly used to identify consumer goods. The sheet 10 has affixed to its first portion 1, and usually also placed over a part of the blocking portion 2, a second identifier 5. The first symbols making up the first identifier 3 are not identifiable by a bar code scanner (not shown), or the like, while the second symbols making up the second identifier 5 are readily identifiable by the scanner. The sheet 10, best as part of its first portion 1, includes a handling area 7 with holes to facilitate manipulation of the sheet 10, particularly when the sheet is in the form of a bag and attached via the holes to a wicket (not shown). The handling area 7 generally does not interfere with the functionality of the series of lines of the blocking portion 2. Too, shown is at least one print area 8 for displaying messages, suffocation warnings for instance. The print area 8 is printed onto the sheet 10 at one or more locations as required by a particular application of the sheet 10. For instance, a fulfillment center for a large online retailer may have specific requirements for messages to print than are required by the center itself.

The embodiment depicts an adhering portion 9 attached to the first portion 1. This adhering portion can be used to seal sheet 10 when the sheet is formed into a bag. I envision the adhering portion being an adhesive tape, but any adhering mechanism will suffice. For instance, the adhering portion 9 could be a magnetic strip. The adhering portion can also be used to attach the sheet 10 to a container (not shown) and thereby cover up a first identifier that is on that container.

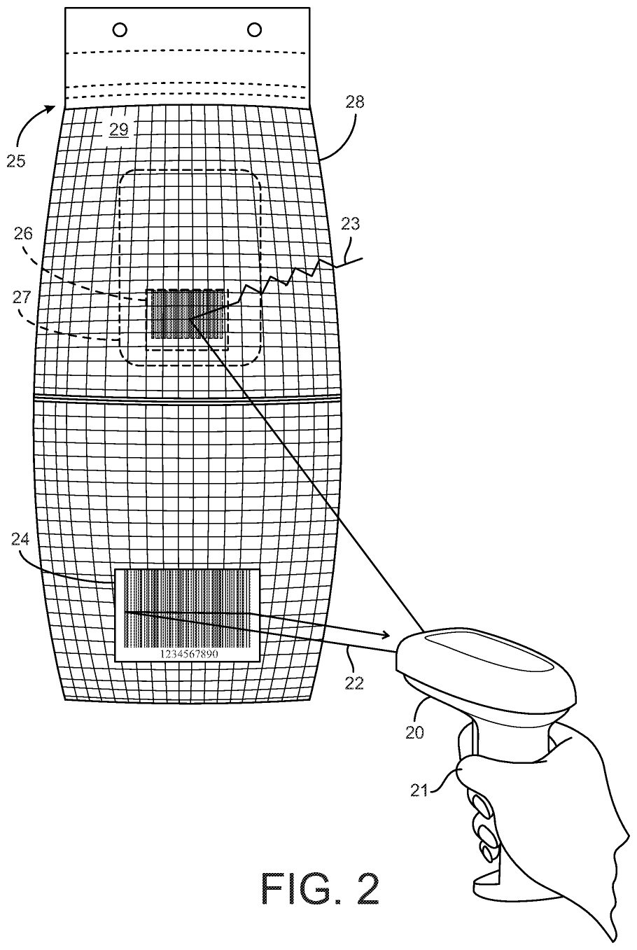

As shown in FIG. 2, another perspective view of an embodiment of the present invention being used in a bar code scanning operation comprises a sheet 25. The sheet 25 functions, for instance through the use of a blocking portion 29 made of a series of lines affixed to a first portion 28 surface, to obscure any item that is placed on either side of the sheet 25. As depicted, an item 27 is placed behind the sheet 25. The item 27 has a first identifier, in this case a UPC label, 26 affixed to its surface. The first portion 28 has a second identifier, another UPC label, 24 affixed to its surface. I envision this being a sticker attached to the sheet over the blocking portion 29. In this instance, the first portion 28 is transparent and the item 27 can be viewed by a user. However, a user, a fulfillment center worker 21 for instance, who uses a bar code scanner 20 to read UPC labels will find that the obscured UPC label, the first identifier 26, is unreadable while the second identifier, the second UPC label, 24 is easily scanned by the scanner. The invention has thus prevented the scanner from reading the bar code label(s) located on items to be shipped and instead reading the bar code labels placed on the sheet, often in the form of a bag, that is being used to ship those items.

More specifically, a fulfillment center worker 21 will often use a bar code reader, or the like, to do her job. The bar code reader 20 will assist in logging the inventory of items that exist in a warehouse (not shown). The bar code scanner 20 emits electromagnetic radiation, usually light waves, that interacts with such a bar code 24 and returns bar code information 22 to the scanner 20. While at the same time failing to read an obscured bar code, 26 for instance, and thus returning none of that bar code information 23. Essentially, the inventive embodiment works to prevent electronic reading of unwanted symbols and allow reading of those that are desired to be read.

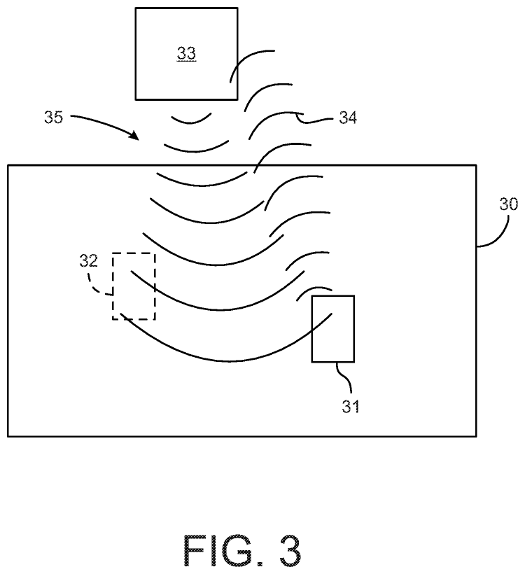

As shown in FIG. 3, a block diagram of an embodiment of the present invention being used in a scanning operation comprises a sheet 30. The sheet 30 has placed behind it a first identifier 32. The sheet 30 has placed in front of it a second identifier 31. The first identifier 32 and the second identifier 31 are located proximate to a symbol interpreter 33. Envisioned as a symbol interpreter is a commonly known UPC scanner. The sheet 30 is interposed between the scanner 33 and the first identifier 32.

Due to the inventive function of the sheet 30 to obscure symbols that are placed behind it, the symbol interpreter 33 is able to identify and interpret 34 the second identifier 31 but is unable to do the same identifying and interpreting 35 of the first identifier 32.

Although the present invention has been described in considerable detail with the reference to certain preferred versions thereof, other versions are possible. For example, there may be more than one first identifier attached to an object and there may be more than one second identifier as well. Also, presently bar code scanners are commonly known, however, future technologies and processes used for reading printed symbols would also benefit from the inventive apparatus' ability to obscure the reading of those symbols not desired to be read. The spirit of the invention is to provide a means for blocking the scanning of undesired item identifiers, such as barcodes, for products being packed then shipped. Therefore, the spirit and scope of the appended claims should not be limited to the description of the preferred versions contained herein.

Any element in a claim that does not explicitly state “means for” performing a specified function, or “step for” performing a specific function, is not to be interpreted as a “means” or “step” clause as specified in 35 U.S.C. § 112, ¶ 6. In particular, the use of “step of” in the claims herein is not intended to invoke the provisions of 35 U.S.C. § 112, ¶ 6.

What I claim is:

1. A sheet for use in operations involving a scanner, the sheet comprising:
a first portion;
a blocking portion;
a second identifier;
the first portion being transparent;
the blocking portion being attached to the first portion;
the second identifier being attached to the blocking portion;
the sheet being interposable between the scanner and at least one first identifier such that the blocking portion obscures the at least one first identifier from scanning by the scanner.

2. The sheet of claim 1 further comprising:
the first portion having at least two holes.

3. The sheet of claim 2 wherein the first portion is attachable and detachable to a wicket via the at least two holes.

4. The sheet of claim 1 further comprising an adhering portion.

5. The sheet of claim 1 wherein the blocking portion is a plurality of markings.

6. The sheet of claim 5 wherein the plurality of markings are printed lines.

7. The sheet of claim 1 wherein the at least one first identifier is a first barcode and the second identifier is a second barcode.

8. The sheet of claim 1 wherein the first portion is formed into a bag.

9. The sheet of claim 1 wherein the first portion is flexible plastic.

10. A sheet for use in operations involving a scanner, the sheet comprising:
a first portion;
a blocking portion;
a second identifier;
the first portion being transparent;
the first portion being flexible plastic;
the first portion having at least two holes;
the blocking portion being attached to the first portion;
the second identifier being attached to the blocking portion;
the sheet being interposable between the scanner and at least one first identifier such that the blocking portion obscures the at least one first identifier from scanning by the scanner;
the first portion being attachable and detachable to a wicket via the at least two holes;
the blocking portion being a plurality of markings;
the plurality of markings being printed lines;
the first portion having an adhering portion.

11. The sheet of claim 10 wherein the at least one first identifier is a first barcode and the second identifier is a second barcode.

12. A sheet for use in operations involving a scanner, the sheet comprising:
a first portion;
a blocking portion;
a second identifier;
the first portion being transparent;
the first portion having at least two holes;
the blocking portion being attached to the first portion;
the second identifier being attached to the blocking portion;
the sheet being interposable between the scanner and at least one first identifier such that the blocking portion obscures the at least one first identifier from scanning by the scanner;
the first portion being attachable and detachable to a wicket via the at least two holes;
the blocking portion being a plurality of marking;
the plurality of markings being printed lines;
the first portion being flexible plastic;
the first portion being formed into a bag.

13. The sheet of claim 12 wherein the at least one first identifier is a first barcode and the second identifier is a second barcode.

14. A sheet used in operations involving a scanner, the sheet comprising:
a first portion;
a blocking portion;
the first portion being transparent;
the blocking portion being a plurality of printed lines;
the first portion having at least two holes;
the first portion being formed into a bag;
the blocking portion being attached to the first portion;
at least one object;
at least one first barcode;
the at least one object being located within the bag;
the at least one first barcode being attached to the at least one object;
a second barcode;
the second barcode being attached to the blocking portion;
the blocking portion being interposable between the scanner and the at least one first barcode;
the at least one first barcode being viewable by a user through the first portion;
the blocking portion obscuring the at least one first barcode from being scanned by the scanner causing the result that the scanner reads only the second barcode when the optical scanner is directed at the bag.

15. The sheet of claim 14 wherein the first portion is attachable and detachable to a wicket via the at least two holes.

16. The sheet of claim 14 further comprising at least one print area for displaying messages.
